(19) United States
(12) Patent Application Publication
(10) Pub. No.: US 2006/0255878 A1
(43) Pub. Date: Nov. 16, 2006

(54) Printed wiring board

(76) Inventors: Samuel M. Babb, Fort Collins, CO (US); Erik D. Swanson, Fort Collins, CO (US); Lowell E. Kolb, Loveland, CO (US)

Correspondence Address: HEWLETT-PACKARD COMPANY;Intellectual Property Administration, P.O. Bo x 272400, Ft. Collins, CO, 80527-2400, US

(21) Appl. No.: 11/489,980

(22) Filed: Jul. 20, 2006

Related U.S. Application Data
(62) Division of application No. 10/832,677, filed on Apr. 27, 2004.

(51) Int. Cl. H03H 7/38

(52) U.S. Cl. 333/33

(57) ABSTRACT

A printed wiring board comprises a first plane having a split formed therein and at least one signal trace disposed on a second plane. The signal trace comprises an increased width in an area of the second plane corresponding to a location of the split.

### BACKGROUND

The problems associated with transmitting signals in a printed wiring board (PWB) or a printed circuit board (PCB) are well known. PWB manufacturers are under constant pressure to provide reduction in board sizes. Production of reduced size PWBs is often complicated by the concurrent market demand for increasingly sophisticated electronic devices and the corresponding requisite density of circuitry and semiconductor devices.

Space considerations often require the use of multi-layer PWBs including multiple layers of dielectric substrates with signal traces formed on the substrates. These signal traces carry data and power signals between components mounted on the board.

Due to design constraints, a layer of a multi-layer PWB may include split planes. When PWB designers desire to minimize the number of board layers, they may employ split planes in one of the layers. As a result, the design may include traces that cross the split planes in a layer directly above or below the split. There are several problems associated with having a trace cross split planes. One of the problems caused by a trace crossing split planes in a layer directly above or below the trace is that it may result in signal reflection and impedance fluctuation at the crossing. When multiple traces cross the split plane, the crosstalk between the traces also increases. Excessive crosstalk can cause errors in signals transmitted across a transmission line.

### SUMMARY

In accordance with an embodiment of the present invention, a printed wiring board comprises a first plane having a split formed therein and at least one signal trace disposed on a second plane. The signal trace comprises an increased width in an area of the second plane corresponding to a location of the split.

In accordance with another embodiment of the present invention, a printed wiring board comprises a first plane having a split formed therein. The printed wiring board also comprises a plurality of signal traces formed on a second plane where at least two of the plurality of signal traces comprise an increased width on the second plane corresponding to a location of the split, and where the increased width of the at least two signal traces are offset from each other relative to a direction of the at least two signal traces.

In accordance with another embodiment of the present invention, a printed wiring board comprises a first plane having a split formed therein and a second plane having a signal trace disposed thereon. The signal trace is adapted to maintain a substantially constant impedance while extending across an area of the second plane corresponding to a location of the split.

### BRIEF DESCRIPTION OF THE DRAWINGS

For a more complete understanding of the present invention, the objects and advantages thereof, reference is now made to the following descriptions taken in connection with the accompanying drawings in which:

FIG. 1 is a perspective view of a portion of a printed wiring board with a signal trace in accordance with an embodiment of the present invention;

FIG. 2 is a perspective view of a portion of a printed wiring board with a signal trace in accordance with an alternative embodiment of the present invention;

FIG. 3 is a top view of a portion of a printed wiring board with a plurality of signal traces in accordance with an alternative embodiment of the present invention;

FIG. 4 is a top view of a portion of a printed wiring board with a plurality of signal traces in accordance with an alternative embodiment of the present invention;

FIG. 5 is a top view of a portion of a printed wiring board with a plurality of signal traces and an alternating pattern of a reference plane split in accordance with an alternative embodiment of the present invention;

FIG. 6 is a top view of a portion of a printed wiring board with a plurality of signal traces and a stairstep-shaped reference plane split in accordance with an alternative embodiment of the present invention;

FIG. 7A is a top view of a portion of a printed wiring board with a virtual ground plane in accordance with an embodiment of the present invention;

FIG. 7B is a sectional view taken along section 7B-7B of the portion of the printed wiring board of FIG. 7A; and

FIG. 8 is a top view of a portion of a printed wiring board with a signal trace in accordance with an alternative embodiment of the present invention.

### DETAILED DESCRIPTION OF THE DRAWINGS

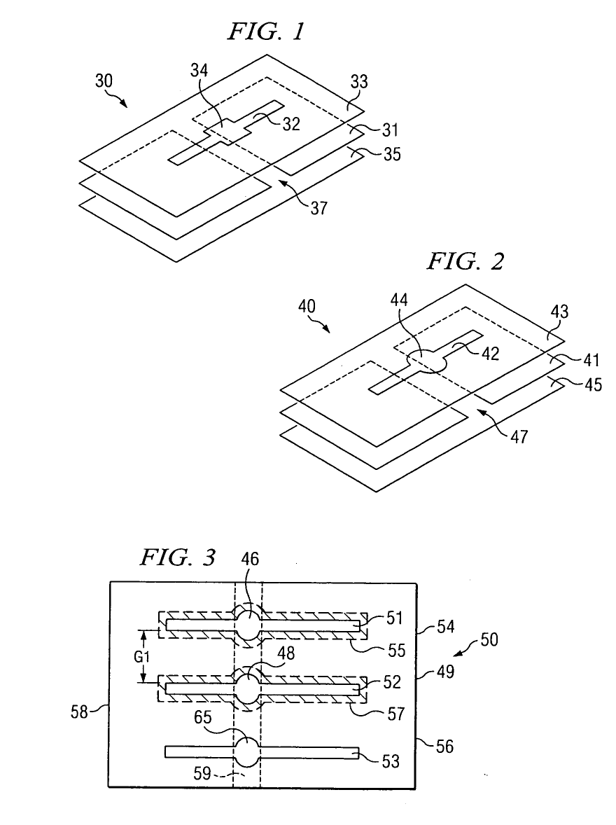

The preferred embodiment of the present invention and its advantages are best understood by referring to FIGS. 1 through 8 of the drawings.

FIG. 1 is a perspective view of a portion of a printed wiring board 30 with a signal trace 32 in accordance with an embodiment of the present invention. Board 30 comprises stacked layers or planes 31, 33, and 35. In FIG. 1, three layers or planes are illustrated; however, it should be understood that board 30 may comprise additional layers or planes. In the embodiment illustrated in FIG. 1, board 30 comprises a reference plane 31, for example a ground plane, disposed between a signal plane 33 and a secondary plane 35. As illustrated in FIG. 1, reference plane 31 has a discontinuity or split 37, thereby forming a split plane 31. A signal trace 32 is provided on signal plane 33. Signal trace 32 extends along board 30 and extends over or spans reference plane split 37. For example, as illustrated in FIG. 1, signal trace 32 extends across or spans split 37 such that at least a portion of signal trace 32 extends through an area of plane 33 corresponding to an area or location of split 37 projected onto plane 33. Signal trace 32 is configured having a non-uniform width across the surface of signal plane 33 to maintain a substantially constant impedance in signal trace 32 across split 37. For example, in the embodiment illustrated in FIG. 1, a portion 34 of trace 32 disposed over reference plane split 37 is wider than other portions of signal trace 32. The local impedance of a signal trace is inversely proportional to the width of the signal trace and directly proportional to the distance between the signal trace and the reference plane adjacent to the signal plane, for example, reference plane 31. Because of split 37, the distance between signal trace 32 and reference plane 31 increases. Thus, by adapting signal trace 32 on plane 33 to have an increased width in an area of plane 33 corresponding to a projection of split 37 onto plane 33, a substantially constant impedance across signal trace 32 is maintained. Additionally, the dimension of the increased width area 34 of trace 32 is sized to obtain a substantially constant or desired impedance based on a distance between plane 33 and split 37.

A technical advantage of an exemplary embodiment is that by making the trace wider over the split, capacitance is introduced over a normally inductive area, thereby countering the affects of inductance and minimizing the impedance and the reflection at the crossing point. Signal integrity is also improved. Another technical advantage of the exemplary embodiment is that designers can route more traces over splits saving valuable board space.

In the embodiment of FIG. 1, the shape of portion 34 of trace 32 is substantially rectangular because the width of trace 32 is increased by an equal amount along the width of split 32. However, the sudden transition of signal trace 32 from a narrow trace to a wider trace may result in overcompensation for the split because of the effect of the electric field created by the portion of the trace in proximity to the split. Therefore, if desired, the width of trace 32 may be increased by differing or varying amounts within the area of split 37 such that the width of trace 32 transitions gradually to a desired width within the area of split 37. Additionally, in the embodiment illustrated in FIG. 1, signal plane 33 having portion 34 of trace 32 is disposed adjacent split plane 31. However, it should be understood that additional layers may be disposed between split plane 31 and a layer having a width-increased signal trace.

FIG. 2 is a perspective view of a portion of a printed wiring board 40 with a signal trace 42 in accordance with an alternative embodiment of the present invention. Board 40 comprises a plurality of stacked layers or planes 41, 43, and 45. In the illustrated embodiment, board 40 comprises a reference plane 41, for example a ground plane, disposed between a signal plane 43 and a secondary plane 45. As illustrated in FIG. 2, reference plane 41 has a discontinuity or split 47, thereby forming a split plane 41. A signal trace 42 is provided on signal plane 43. Signal trace 42 extends along board 40 and extends across or spans reference plane split 47 such that at least a portion of trace 42 extends through an area of plane 43 corresponding to an area or location of split 47 projected onto plane 43. The width of signal trace 42 is non-uniform across the surface of signal plane 43. Signal trace 42 is adapted such that portion 44 of signal trace 42 is wider than other portions of trace 42. The width of portion 44 of signal trace 42 changes gradually to result in a substantially oval shape. A technical advantage of a substantially oval-shaped portion 44 is that it takes into account effects of fringe electric fields caused by the portion of the trace in proximity to reference plane split 47 to maintain the impedance of the trace substantially constant. However, it should be understood that portion 44 may be configured having a circular or non-circular geometric configuration.

FIG. 3 is a top view of a portion of a printed wiring board 50 with signal traces 51, 52, and 53. Board 50 comprises stacked layers or planes 49, 54, and 56 similar to respective planes 41, 43 and 45 of FIG. 2. For example, in the embodiment illustrated in FIG. 3, board 50 comprises a reference plane 49, for example a ground plane, disposed between a signal plane 54 and a secondary plane 56. As illustrated in FIG. 3, reference plane 49 has a discontinuity or split 59, thereby forming a split plane 49. Signal traces 51, 52 and 53 are provided on signal plane 54. In FIG. 3, three signal traces are shown to illustrate problems associated with multiple signal traces extending across or through an area of plane 54 corresponding to an area or location of split 59 projected onto plane 54. However, if desired, a fewer or greater number of signal traces may be provided. Each signal trace 51, 52, 53 comprises a wider portion 46, 48, and 65, respectively, over split 59. Since split 59 is on reference plane 49, it is shown in dashed lines. Like a uniform signal trace, a non-uniform signal trace may have a crosstalk zone surrounding it. Excessive crosstalk may cause errors in received signals. In FIG. 3, a crosstalk zone 55 is associated with signal trace 51, and a crosstalk zone 57 is associated with signal trace 52. In order to avoid overlapping of the crosstalk zones associated with the signal traces, it is desirable to keep a minimum separation between the signal traces. In the exemplary embodiment of FIG. 3, the minimum separation is denoted by G1. The value of G1 in part determines the width of board 50—the smaller the value of G1, the smaller the width of the board. In the embodiment illustrated in FIG. 3, split 59 is generally parallel to an edge 58 of printed wiring board 50 or substantially perpendicular to an orientation or direction of traces 52, 52 and 53. Thus, each signal trace on signal plane 54 crosses split 59 at approximately the same distance from edge 58. Furthermore, because the signal traces cross reference plane split 59 at the same distance from edge 58, the increase in the width of the traces occurs at the same distance from edge 58, thereby resulting in decreased separation between traces and a greater likelihood of crosstalk zone overlap, which may therefore necessitate an increase in board 50 width to compensate for the decreased trace separation.

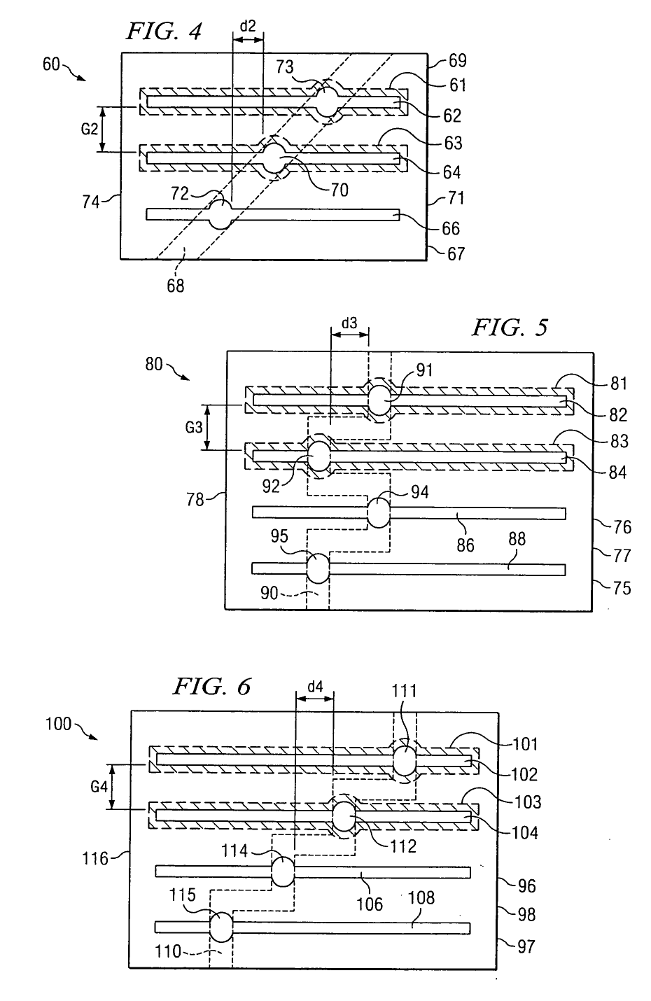

FIG. 4 is a top view of a portion of a printed wiring board 60 with signal traces 62, 64, 66 according to an embodiment of the invention. Board 60 comprises stacked layers or planes 67, 69, and 71 similar to respective planes 41, 43 and 45 of FIG. 2. For example, in the embodiment illustrated in FIG. 4, board 60 comprises a reference plane 67, for example a ground plane, disposed between a signal plane 69 and a secondary plane 71. Reference plane 67 has a discontinuity or split 68, thereby forming a split plane 67. Since split 68 is on reference plane 67, it is shown in dashed lines. Signal traces 62, 64 and 66 are provided on signal plane 69. In FIG. 4, three signal traces are shown. However, if desired, a fewer or greater number of signal traces may be provided. Signal traces 62, 64, 66 extend across or over split 68 such that at least a portion of traces 62, 64 and 66 extend through or across plane 69 corresponding to an area or location of split 68 projected onto plane 69. Each signal trace 62, 64, 66 comprises a wider portion 73, 70 and 72, respectively, over split 68. Like a uniform signal trace, a non-uniform signal trace may have a crosstalk zone surrounding it. A crosstalk zone 61 is associated with signal trace 62, and a crosstalk zone 63 is associated with signal trace 64. In the exemplary embodiment of FIG. 4, the separation between adjacent traces is denoted by G2. The distance between wider portion 70 of signal trace 64 and wider portion 72 of signal trace 66 along the length of the traces is denoted by d2.

In PWB 60, reference plane split 68 is not parallel to an edge 74 of printed wiring board 60. For example, in the embodiment illustrated in FIG. 4, split 68 and traces 62, 64 and 66 are configured having a non-perpendicular angular relationship relative to each other. Thus, the signal traces on signal plane 69 cross reference plane split 68 at different distances from edge 74, thereby causing a reduction in the crosstalk because the wider portions of adjacent traces are further apart from each other. Furthermore, because the increase in the width of the traces is offset among the traces and occurs at different distances from edge 58, the separation G2 between adjacent signal traces may be less than the minimum separation between adjacent signal traces of PWB 50 of FIG. 3. Thus, in some embodiments, for the same number of signal traces, the width of PWB 60 of FIG. 4 is less than the width of PWB 50 of FIG. 3. Therefore, for the same number of signal traces, a PWB of smaller width may be provided by changing the orientation of the reference plane split in order to stagger the location of the wider portions of the signal traces. Accordingly, while a reduction in size of a printed wiring board may not be required or desired, in addition to reducing crosstalk, embodiments of the present invention enable a reduction in the size of the printed wiring board. In the embodiment illustrated in FIG. 4, split 68 extends across the entire plane 69 in a non-perpendicular angular orientation relative to an orientation of traces 62, 64 and 66. However, it should be understood that split 68 may also be configured to transition from a non-perpendicular angular orientation to a perpendicular orientation relative to traces 62, 64 and 66 at various locations of board 60.

The reference plane splits may be of any shape. As examples, and not by way of limitation, in FIG. 5, the reference plane split comprises a staggered or alternating pattern, and in FIG. 6, the reference plane split is stairstep-shaped. For the same number of signal traces, a PWB of smaller width may be provided by changing the shape of the reference plane split.

FIG. 5 is a top view of a portion of a printed wiring board 80 with signal traces 82, 84, 86, 88 crossing a staggered or alternating pattern of a reference plane split 90. Board 80 comprises stacked layers or planes 75, 76, and 77 similar to respective planes 41, 43 and 45 of FIG. 2. For example, in the embodiment illustrated in FIG. 5, board 80 comprises a reference plane 75, for example a ground plane, disposed between a signal plane 76 and a secondary plane 77. As illustrated in FIG. 5, reference plane 75 has a discontinuity or split 90, thereby forming a split plane 75. Since split 90 is on reference plane 75, it is shown in dashed lines. Signal traces 82, 84, 86 and 88 are provided on signal plane 76. In FIG. 5, four signal traces are shown. Of course, if desired, a fewer or greater number of signal traces may be provided. Signal traces 82, 84, 86 and 88 extend across or over split 90 such that at least a portion of traces 82, 84, 86 and 88 extend through or over a portion of plane 76 corresponding to an area or location of split 90 projected onto plane 76. Each signal trace 82, 84, 86 and 88 comprises a wider portion 91, 92, 94 and 95, respectively, over split 90. A crosstalk zone 81 is associated with signal trace 82, and a crosstalk zone 83 is associated with signal trace 84. In the exemplary embodiment of FIG. 5, the separation between the adjacent traces is denoted by G3. In PWB 80, split 90 is configured having an alternating or staggered pattern such that portions of split 90 are oriented generally parallel to an edge 78 of PWB 80 or substantially perpendicular to traces 82, 84, 86 and 88 where traces 82, 84, 86 and 88 extend over or across split 90 while remaining portion of split 90 are configured generally parallel to traces 82, 84, 86 and 88. The alternating or staggered pattern of split 90 may comprise a zigzag, zipper, or other type of pattern such that an alternating or staggered pattern of wider portions 91, 92, 94 and 95 are formed. Thus, in the embodiment illustrated in FIG. 5, the wider portions of adjacent signal traces are offset from each in a repeating pattern, thereby resulting in no adjacent signal traces having wider portions that are equidistant from edge 78 of board 80.

In the embodiment illustrated in FIG. 5, at least one set of signal traces on signal plane 76 crosses split 90 at the same distance from edge 78, while at least another set of signal traces crosses split 90 at a distance from edge 78 that is different from the first set. Thus, for example, traces 82 and 86 cross split 90 at the same distance from edge 78, and traces 84 and 88 cross split 90 at the same distance from edge 78. Thus, the traces on signal plane 76 cross split 90 at different distances from edge 78. Because the increase in the width of adjacent signal traces occurs at different distances from edge 78, the minimum separation G3 between adjacent signal traces may be less than the minimum separation G1 between adjacent signal traces of PWB 50 of FIG. 3. Thus, in some embodiments, for the same number of signal traces, the width of PWB 80 of FIG. 5 is less than the width of PWB 50 of FIG. 3.

Furthermore, by providing a staggered or alternating pattern of split 90 as illustrated in FIG. 5, a distance d3 between the wider portions of adjacent signal traces may be increased without increasing the width of PWB 80. Thus, for example, in the embodiment illustrated in FIG. 5, the distance d3 between wider portion 92 of signal trace 84 and wider portion 91 of signal trace 82 is greater than distance d2 of PWB 60 of FIG. 4. This results in a reduction in crosstalk. The staggered or alternating pattern of split 90 also enables a bus of associated traces to cross the split at approximately the same distance from the board edge. Furthermore, because d3 is greater than d2, the separation G3 between adjacent signal traces in PWB 80 may be made less than separation G2 between adjacent signal traces in PWB 60 of FIG. 4. Thus, in some embodiments, for the same number of traces, the width of PWB 80 of FIG. 5 is less than the width of PWB 60 of FIG. 4.

FIG. 6 is a top view of a portion of a PWB 100 with signal traces 102, 104, 106, 108 crossing a stairstep-shaped reference plane split 110. Board 100 comprises stacked layers or planes 96, 97, and 98 similar to respective planes 41, 43 and 45 of FIG. 2. For example, in the embodiment illustrated in FIG. 6, board 100 comprises a reference plane 96, for example a ground plane, disposed between a signal plane 97 and a secondary plane 98. As illustrated in FIG. 6, reference plane 96 has a discontinuity or split 110, thereby forming a split plane 96. Since split 110 is on reference plane 96, it is shown in dashed lines. Signal traces 102, 104, 106 and 108 are provided on signal plane 97. In FIG. 6, four signal traces are shown. Of course, if desired, a fewer or greater number of signal traces may be provided. Signal traces 102, 104, 106 and 108 extend across or over split 110 such that at least a portion of traces 102, 104, 106 and 108 extend across or through an area of plane 97 corresponding to an area or location of split 110 projected onto plane 97. Each signal trace 102, 104, 106 and 108 comprises a wider portion 111, 112, 114 and 115, respectively, over split 110.

In the embodiment illustrated in FIG. 6, a crosstalk zone 101 is associated with signal trace 102, and a crosstalk zone 103 is associated with signal trace 104. In the embodiment illustrated in FIG. 6, the separation between the adjacent traces is denoted by G4. In PWB 100, split 110 is stairstep-shaped. Thus, the signal traces on signal plane 97 cross reference plane split 110 at different distances from an edge 116, thereby producing an offset pattern of the wider portions of the traces. Because the increase in the width of the signal traces occurs at different distances from edge 116, the minimum separation G4 between adjacent signal traces may be less than the minimum separation G1 between adjacent signal traces of PWB 50 of FIG. 3. Thus, in some embodiments, for the same number of signal traces, the width of PWB 100 of FIG. 6 is less than the width of PWB 50 of FIG. 3.

Furthermore, by providing a stairstep-shaped split, the distance d4 between the wider portions of adjacent signal traces may be increased without increasing the width of PWB 100. Thus, for example, the distance d4 between wider portion 112 of signal trace 104 and wider portion 114 of signal trace 106 is greater than distance d2 of PWB 60 of FIG. 4. This results in a reduction in crosstalk. Furthermore, because d4 is greater than d2, the separation G4 between adjacent signal traces in PWB 100 may be made less than separation G2 between adjacent signal traces in PWB 60 of FIG. 4. Thus, in some embodiments, for the same number of traces, the width of PWB 100 of FIG. 6 may be less than the width of PWB 60 of FIG. 4.

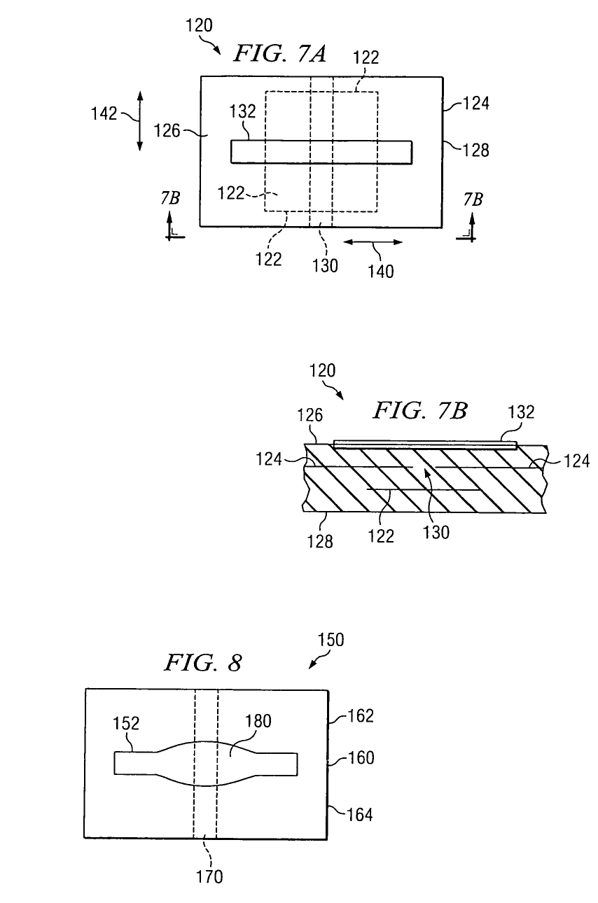

FIG. 7A is a top view of a portion of a printed wiring board 120 with a virtual ground plane 122 in accordance with an embodiment of the present invention, and FIG. 7B is a sectional view taken along section 7B-7B of printed wiring board 120.

Board 120 comprises stacked layers or planes 124, 126, and 128. In the embodiment illustrated in FIGS. 7A and 7B, board 120 comprises a reference plane 124, for example a ground plane, disposed between a signal plane 126 and a secondary plane 128. As illustrated in FIG. 7B, reference plane 124 has a discontinuity or split 130, thereby forming a split plane 124. A signal trace 132 is provided on signal plane 126. Signal trace 132 extends along board 120 and extends across or over split 130 such that at least a portion of trace 132 is disposed on or extends through an area of plane 126 corresponding to an area or location of split 130 projected onto plane 126.

Board 120 comprises a virtual ground plane 122 that is disposed between reference plane 124 and secondary plane 128. In the embodiment illustrated in FIGS. 7A and 7B, virtual ground plane 122 is disposed below reference plane split 130. Placement of virtual ground plane 122 below reference plane split 130 minimizes the current return path. The impedance of signal trace 132 is directly proportional to the distance between signal trace 132 and the plane adjacent to the signal plane. Because of the presence of reference plane split 130, the distance between the portion of signal trace 132 above reference plane split 130 and the adjacent plane, for example secondary plane 128, increases. By providing an additional plane, for example virtual ground plane 122, below reference plane split 130 between reference plane 124 and secondary plane 128, the distance between the portion of signal trace 132 above reference plane split 130 and the adjacent plane is reduced, thereby reducing the effect of reference plane split 130 on the impedance of signal trace 132.

In the embodiment illustrated in FIGS. 7A and 7B, virtual ground plane 122 is sized having a length shorter than a length of secondary plane 128 as measured in a longitudinal direction indicated generally by 140. The dimension of virtual ground plane 122 along a direction that is orthogonal to the signal trace is referred to herein as the width of virtual ground plane 122, the width direction indicated generally by 142. In some embodiments, the length of virtual ground plane 122 is greater than the width of reference plane split 130, and the width of virtual ground plane 122 is greater than the width of signal trace 132. In other embodiments, the length of virtual ground plane 122 is at least equal to the width of the split plus a factor of the distance of the separation between reference plane 124 and virtual ground plane 122. In other embodiments, the width of virtual ground plane 122 is at least equal to the width of the signal trace plus a factor of the distance of separation between the signal trace and virtual ground plane 122.

FIG. 8 is a top view of a portion of a printed wiring board 150 with a signal traces 152 according to an embodiment of the invention. Board 150 comprises stacked layers or planes 160, 162 and 164 similar to respective planes 41, 43 and 45 of FIG. 2. For example, in the embodiment illustrated in FIG. 8, board 150 comprises a reference plane 160, for example a ground plane, disposed between a signal plane 162 and a secondary plane 164. Reference plane 160 has a discontinuity or split 170, thereby forming a split plane 160. Since split 170 is on reference plane 160, it is shown in dashed lines. Signal trace 152 is provided on signal plane 162. Signal trace 152 extends across or over split 170 such that at least a portion of trace 152 extends across plane 162 corresponding to an area or location of split 170 projected onto plane 162. As illustrated in FIG. 8, signal trace 152 comprises a wider portion 180 over split 170 to maintain a substantially constant or desired impedance over split 170. In the embodiment illustrated in FIG. 8, signal trace 152 is configured such that a width of trace 152 increases as trace 152 approaches or nears split 170. For example, in the embodiment illustrated in FIG. 8, trace 152 is configured to transition gradually to wider portion 180 in an area of plane 162 outside of split 170. Additionally, in the embodiment illustrated in FIG. 8, wider portion 180 is configured having a variable width over split 170. Thus, embodiments of the present invention enable a width of signal trace 152 to be increased or decreased within an area of plane 162 corresponding to split 170 and/or to be increased or decreased as signal trace approaches or nears an area of plane 162 corresponding to split 170.

Although in the illustrated embodiment of FIGS. 3 through 6, the signal traces are of non-uniform width, the invention is not so limited. In alternative embodiments, the signal traces may be of uniform width. For example, in some embodiments, some of the signal traces may be of non-uniform width and others may be of uniform width. Although in the illustrated embodiment of FIGS. 7A and 7B, the signal trace is of uniform width, the invention is not so limited. In alternative embodiments, the signal trace may be of non-uniform width. In another alternative embodiment, some of the signal traces may be of non-uniform width and others may be of uniform width.

Additionally, in the embodiments illustrated in FIGS. 1 through 6 and 8, widened areas or portions of the signal traces are referred to as being “over” a plane split, it should be understood that the widened areas or portions of traces may be “over” or “under” a plane split depending on a reference point of view. Additionally, in FIGS. 1 through 8, a single split reference plane is illustrated. However, it should be understood that multiple split planes may be used at various levels of the printed wiring board and/or a particular plane may comprise multiple splits such that signal traces have multiple wider portions corresponding to the various split locations. Further, in the embodiment illustrated in FIGS. 7A and 7B, virtual ground plane 122 is described as being “below” reference plane split 130. However, it should be understood that virtual ground plane 122 may also be disposed “above” reference plane split 130 based on a reference point of view.

Although various embodiments of the present invention have been described herein with reference to printed wiring boards, the teachings of the various embodiments may also be used with reference to printed circuit boards.

1-10. (canceled)

11. A printed wiring board, comprising:
a first plane having a split formed therein; and
a plurality of signal traces formed on a second plane, at least two of the plurality of signal traces having an increased width on the second plane corresponding to a location of the split, the increased width of the at least two signal traces offset from each other relative to a direction of the at least two signal traces.

12. The printed wiring board of claim 11, wherein the increased width of at least one of the at least two signal traces varies within the area of the second plane corresponding to the location of the split.

13. The printed wiring board of claim 11, wherein at least one of the at least two signal traces transitions to the increased width as the at least one signal trace nears the area of the second plane corresponding to the location of the split.

14. The printed wiring board of claim 11, wherein the split comprises an alternating pattern.

15. The printed wiring board of claim 11, wherein the split comprises a stairstep pattern.

16. The printed wiring board of claim 11, wherein at least a portion of the split extends along the first plane in a non-perpendicular orientation relative to an orientation of the plurality of signal traces.

17. The printed wiring board of claim 11, wherein at least a portion of the split extends along the first plane in a non-perpendicular orientation relative to an edge of the printed wiring board.

18. The printed wiring board of claim 11, wherein the increased width of at least one of the at least two signal traces remains constant within the area of the second plane corresponding to the location of the split.

19. The printed wiring board of claim 11, wherein a dimension of the increased width of at least one of the at least two signal traces corresponds to a distance between the first plane and the second plane.

20-26. (canceled)

27. A printed wiring board, comprising:
a first plane having a signal trace disposed thereon;
a second plane disposed between a third plane and the first plane, the second plane having a split formed therein; and
a fourth plane sized smaller than the third plane and disposed between the third plane and the second plane.

28. The printed wiring board of claim 27, a size of the fourth plane based on a size of the split.

29. The printed wiring board of claim 27, a width of the fourth plane greater than a width of the signal trace.

30. The printed wiring board of claim 27, a length of the fourth plane greater than a width of the split.

31. The printed wiring board of claim 27, a size of the fourth plane based on a distance between the second plane and the fourth plane.

32. The printed wiring board of claim 27, a size of the fourth plane based on a distance between the first plane and the fourth plane.

33. A printed wiring board, comprising:
a first plane having a split formed therein; and
at least one signal trace disposed on a second plane, the signal trace having an increased width in an area of the second plane corresponding to a location of the split, the increased width varying within the area of the second plane corresponding to the location of the split.

34. The printed wiring board of claim 33, wherein the signal trace transitions to the increased width as the signal trace nears the area of the second plane corresponding to the location of the split.

35. The printed wiring board of claim 33, wherein at least a portion of the split extends along the first plane in a non-perpendicular orientation relative to an orientation of the signal trace.

36. The printed wiring board of claim 33, wherein the split comprises an alternating pattern.

37. The printed wiring board of claim 33, wherein the split comprises a stairstep pattern.

38. The printed wiring board of claim 33, wherein the split is disposed in a non-perpendicular orientation relative to an edge of the printed wiring board.

39. The printed wiring board of claim 33, wherein the increased width remains constant within the area of the second plane corresponding to the location of the split.

40. The printed wiring board of claim 33, further comprising wherein a dimension of the increased width corresponds to a distance between the first plane and the second plane.

41. The printed wiring board of claim 33, wherein the increased width comprises a non-circular configuration.

42. A printed wiring board, comprising:
a first plane having a split formed therein; and
a second plane having a signal trace disposed thereon, the signal trace adapted to maintain a substantially constant impedance while extending across an area of the second plane corresponding to a location of the split, the signal trace having a width varying within the area of the second plane corresponding to the location of the split.

43. The printed wiring board of claim 42, wherein the signal trace is adapted to maintain the substantially constant impedance based on a distance between the first and second planes.

44. The printed wiring board of claim 42, wherein the split is disposed in a non-perpendicular orientation relative to an orientation of the signal trace.

45. The printed wiring board of claim 42, wherein the split is disposed in a non-perpendicular orientation relative to an edge of the printed wiring board.

46. The printed wiring board of claim 42, wherein the split comprises a staggered pattern.

47. The printed wiring board of claim 42, wherein the split comprises a stairstep pattern.

48. The printed wiring board of claim 42, wherein a width of the signal trace is modified to maintain the substantially constant impedance.
